(19) United States
(12) Patent Application Publication
(10) Pub. No.: US 2016/0148700 A1
(43) Pub. Date: May 26, 2016

(54) MEMORY SYSTEM AND DATA PROCESING METHOD FOR MEMORY

(71) Applicant: WILUS INSTITUTE OF STANDARDS AND TECHNOLOGY INC., Seoul (KR)

(72) Inventor: Hyunoh OH, Gwacheon-si, Gyeonggi-do (KR)

(73) Assignee: WILUS INSTITUTE OF STANDARDS AND TECHNOLOGY INC., Seoul (KR)

(21) Appl. No.: 14/903,601

(22) PCT Filed: Jul. 8, 2014
(86) PCT No.: PCT/KR2014/006099

§ 371 Date: Jan. 8, 2016

Related U.S. Application Data
(60) Provisional application No. 61/843,898, filed on Jul. 8, 2013.

(51) Int. Cl. G11C 16/16; G11C 16/26

(52) U.S. Cl. CPC G11C 16/16; G11C 16/26

(57) ABSTRACT

The present invention relates to a memory system and a data processing method in a memory, and more particularly, to a memory system for efficiently processing data and a data processing method in a memory.

To this end, the present invention provides a data processing method in a memory, including: programming data by applying a voltage having a predetermined nominal value to a pilot cell at a predetermined position in the memory; reading a written voltage value of the pilot cell; adjusting a nominal value corresponding to the data based on the read voltage value of the pilot cell; and programming the data to a data cell of the memory by using the adjusted nominal value and a memory system using the same.

### TECHNICAL FIELD

The present invention relates to a memory system and a method for processing data in the memory, and more particularly, to a memory system for efficiently processing data and a method for processing data in the memory.

### BACKGROUND ART

A memory device is a most essential microelectronic element in a digital logic design. The memory device is largely divided into a volatile memory device and a non-volatile memory device. Although power of the non-volatile memory device is cut off, the non-volatile memory device can store data. The data stored in the non-volatile memory can be permanent or reprogrammed according to a memory manufacturing technique. The non-volatile memory device can be used in applications of various industrial fields.

As a representative example of the non-volatile memory, a flash memory is provided. The flash memory can be used in numerous media storing data, such as a smart phone, a digital camera, a solid-state drive (SSD), and a black box. In particular, since the SSD using a NAND flash memory has small power consumption, can be miniaturized, and is resistant to impact as compared with a hard disk drive (HDD), the SSD is widely used as storage media in a laptop, a desktop, and a server. Furthermore, in recent years, there is a trend that with the development of the smart phone and the SSD, availability of the NAND flash memory has gradually increased.

Basically, a cell of the flash memory can write and erase data by filling and emptying electrons in and from a floating gate.

In more detail, when voltage enough to cause a tunnel effect is applied to a control gate in a state of an empty cell, some of the electrons which move from a source to a drain pass through an oxide film which is an insulator due to an influence of an electric field generated according to the applied voltage to fill the electrons of the floating gate. Next, when the applied voltage is cut off, the electrons filled in the floating gate covered with the insulator are confined in the floating gate. Therefore, the electrons can be kept in a state in which the electrons are filled in the floating gate even though power is not supplied. A write operation of the flash memory cell can be implemented by the aforementioned operations.

When positive voltage which may cause a tunnel release is applied to a P layer while the electrons are filled in the floating gate, the electrons confined in the floating gate can be discharged to the outside of the floating gate through an insulating layer. As a result, the cell may return to an empty state again. An erase operation of the flash memory cell can be implemented by the aforementioned operations.

However, the NAND flash memory has a disadvantage in that overwrite in-place of data is not permitted unlike a DRAM or the HDD. That is, for overwriting, a part previously written in the memory cell is erased and thereafter, overwriting needs to be performed. In other words, before data is written in the flash memory, the data needs to return to an initial state or an erased state. This is referred to as an erase-before-write operation. Therefore, a problem occurs, in which the entire block is first erased and thereafter, all pages in the corresponding block need to be rewritten even when changing data of 1 byte due to a characteristic of a cell of which overwriting is impossible (herein, the minimum wise of writing and reading of the NAND flash memory is the page and the minimum wise of erasing is the block).

Since a state change of the memory cell described above causes abrasion of the memory cell, only overwriting at a predetermined number of times can be generally permitted in the cell of the flash memory. That is, when the predetermined number of overwriting times is exceeded, additional overwriting is not possible any longer and only reading is just possible.

Due to an attribute of the data that is stored in the flash memory, updated periods may vary according to a type of data. For example, most of the data files with a small capacity are frequently written and erased (that is, updated), while most of data files with a large capacity may be accessed only for the reading operations. Further, meta data may be one of hot data which are more frequently updated than general data. Accordingly, there is a need for a method of increasing the lifespan of the flash memory by considering the viewpoints.

There is a trend that a storage capacity of the flash memory has gradually increased. Moreover, a block size and a page size in the flash memory have also increased for efficient addressing. However, since a large majority of files of which the amount used is largeare small-sized files even up to now, the page may be inefficiently used in the situation in which only one file can be stored in one page.

Meanwhile, all software operating in the processor needs to be compiled in order to be suitable for a target system. Optimization of the complier may have a large effect on performance of the application. In order to implement the optimization, a processing speed and memory utilization are focused. Software pipelining and a loop invariant code operation are examples of the optimization of the complier.

In an embedded or mobile environment, the computing system has a problem related with high power consumption. Some low-power processors interrupt power supply in order to remove leakage current in an idle state. However, in this case, since date stored in the volatile memory such as volatile registers may be lost, there is a disadvantage in that the system restoration may be inefficient or impossible.

In order to solve the problem related with the data backup of the low-power processor, techniques for the non-volatile processor may be proposed. The non-volatile processor may use a non-volatile memory for replacing a general CMOS register. However, due to a physical attribute of the non-volatile memory, in a non-volatile processor (NVP) paradigm, in order to implement the aforementioned compiler optimization, there may be a new condition such as an increase in lifespan of the processor hardware.

### DISCLOSURE

### Technical Problem

The present invention has been made in an effort to efficiently use a memory system.

### Technical Solution

An exemplary embodiment of the present invention provides a compiling method including: detecting data to be allocated to a register from a source code; generating correlation information indicating a correlation between the data stored in each of one or more registers and the data to be allocated; determining a target register to allocate the data to be allocated among the registers based on the correlation information; and allocating the data to be allocated to the determined target register.

In this case, the determining may include determining a register which is least used as a target register when a target register having a correlation equal to or more than a predetermined correlation with the data to be allocated is not determined.

The compiling method may further include determining the register which is least used as the target register at least partially based on the number of use times of the register written by a wear leveling module.

The allocating may include allocating the data to be allocated to the target register without rewriting when the correlation between the data to be allocated and the data stored in the target register is equal to or more than a predetermined correlation.

The determining may include determining a register currently storing data having a highest correlation with the data to be allocated among the registers as the target register based on the correlation information.

The generating of the correlation information may include reading values of data currently stored in one or more respective registers on the virtual processor by configuring a virtual processor; comparing the read data values and the data value detected from the source code; and generating the correlation information based on the comparison.

The allocating may include allocating to the same register two or more data having a correlation which is equal to or more than a predetermined correlation.

Another exemplary embodiment of the present invention provides a computer-readable medium storing following commands for converting a source code to a machine language code, wherein the commands include a command for detecting data to be allocated to a register from the source code, a command for generating correlation information representing a correlation between data stored in each of one or more registers and the data to be allocated, and a command for determining a target register to be allocated with the data to be allocated among the registers based on the correlation information, and a command for allocating the data to be allocated to the determined target register.

Yet another exemplary embodiment of the present invention provides a processor including: one or more registers to which data detected from a source code may be allocated; and a controller controlling the processor, in which the controller generates correlation information representing a correlation between data stored in each of one or more registers and the data to be allocated, determines a target register to be allocated with the data to be allocated among the registers based on the correlation information, and allocates the data to be allocated to the determined target register.

Still yet another exemplary embodiment of the present invention provides a data processing method in a memory, including: programming data by applying a voltage having a predetermined nominal value to a pilot cell at a predetermined position in the memory; reading a written voltage value of the pilot cell; adjusting a nominal value corresponding to the data based on the read voltage value of the pilot cell; and programming the data to a data cell of the memory by using the adjusted nominal value.

In this case, in the reading, the voltage value of the pilot cell may be read with higher resolution than a voltage step among the respective data for the programming.

The adjusting may include calculating a difference value between the read voltage value of the pilot cell and the predetermined nominal value, and obtaining the adjusted nominal value by adding the calculated difference value to the predetermined nominal value.

The adjusting may include calculating a ratio between the read voltage value of the pilot cell and the predetermined nominal value, and obtaining the adjusted nominal value by scaling the predetermined nominal value based on the calculated ratio.

The pilot cell may be positioned in the same block or page as the data cell.

The data processing method may further include: obtaining information on the number of erase times of a block or information on the number of write times of a page at which the pilot cell is positioned; and shifting the position of the pilot cell based on the information on the number of erase times or the information on the number of write times.

The pilot cell may include a plurality of cells corresponding to a plurality of nominal values used for programming the memory, respectively.

Still another exemplary embodiment of the present invention provides a memory system including: a memory having a plurality of physical blocks, each of the plurality of physical blocks including a plurality of pages; and a memory controller configured to control the memory, in which the memory controller includes a programming module for writing/erasing data in/from the memory, a reading module for reading the data written in the memory, and a control module controlling the programming module and the reading module, the programming module programs data by applying voltage having a predetermined nominal value to a pilot cell at a predetermined position in the memory, the reading module reads a written voltage value of the pilot cell, and the control module adjusts a nominal value corresponding to the data based on the read voltage value of the pilot cell and programs the data to a data cell of the memory by using the adjusted nominal value.

Still yet another exemplary embodiment of the present invention provides data processing method in a memory, including: programming data to a pilot cell and a data cell in the memory by using voltage of a predetermined nominal value, the pilot cell indicating a cell at a predetermined position corresponding to each of at least one nominal value used for programming the memory; reading a written voltage value of the pilot cell; setting a threshold voltage value for reading the data cell by referring to the read voltage value of the pilot cell; and reading the data of the data cell of the memory based on the set threshold voltage value.

In this case, in the reading, the voltage value of the pilot cell may be read with higher resolution than a voltage step among the respective data for the programming.

The pilot cell may be positioned in the same block or page as the data cell.

The data processing method may further include: obtaining information on the number of erase times of a block or information on the number of write times of a page at which the pilot cell is positioned; and shifting the pilot cell based on the information on the number of erase times or the information on the number of write times.

The pilot cell may include a plurality of cells corresponding to a plurality of nominal values used for programming the memory, respectively.

The setting of the threshold voltage value may include obtaining read voltage values of a plurality of pilot cells programmed by using the same nominal value in the memory, and the threshold voltage value may be set based on an average of the obtained read voltage values of the plurality of pilot cells.

Still yet another exemplary embodiment of the present invention provides a memory system including: a memory having a plurality of physical blocks, each of the plurality of physical blocks including a plurality of pages; and a memory controller configured to control the memory, in which the memory controller includes a programming module for writing/erasing data in/from the memory, a reading module for reading the data written in the memory, and a control module controlling the programming module and the reading module, the programming module programs data to a pilot cell and a data cell in the memory by using voltage having a predetermined nominal value, the pilot cell is a cell at a predetermined position corresponding to each of at least one nominal value used for programming the memory, the reading module reads a written voltage value of the pilot cell, the control module sets a threshold voltage value for reading the data cell by referring to the read voltage value of the pilot cell, and the reading module reads the data of the memory cell of the memory based on the set threshold voltage value.

### Advantageous Effects

According to the exemplary embodiments of the present invention, the memory system may be efficiently used.

### DESCRIPTION OF DRAWINGS

FIG. 1 is a diagram schematically illustrating a memory system according to an aspect of the present invention.

FIG. 2 schematically illustrates the memory system according to the aspect of the present invention.

FIG. 3 illustrates a file auto save method with time in the memory system according to an exemplary embodiment of the present invention.

FIG. 4 illustrates a flowchart for steps processing data in the file auto save in the memory system according to the aspect of the present invention.

FIG. 5 illustrates a process of allocating data to a target system through a compiling system from a source code by using components according to an exemplary embodiment of the present invention.

FIG. 6 schematically illustrates a target system according to an exemplary embodiment of the present invention.

FIG. 7 illustrates an example in which an existing compiler allocates data to a register.

FIG. 8 illustrates an example in which a compiler allocates data to a register according to an exemplary embodiment of the present invention.

FIG. 9 is a flowchart illustrating a method of allocating data to a register according to an exemplary embodiment of the present invention.

FIG. 10 exemplarily illustrates a data block including pilot cells according to an aspect of the present invention.

FIG. 11 exemplarily illustrates a change in arrangement of pilot cells according to a programming count and a page according to an aspect of the present invention.

FIG. 12 exemplarily illustrates a reading method using pilot cells in a page according to an aspect of the present invention.

FIG. 13 exemplarily illustrates a change in threshold voltage after data programming.

FIG. 14 exemplarily illustrates a voltage reading mechanism using pilot cells according to an aspect of the present invention.

FIG. 15 exemplarily illustrates a voltage reading method of a data cell using a switch according to an aspect of the present invention.

FIG. 16 exemplarily illustrates a data cell reading method using a switch according to an aspect of the present invention.

FIG. 17 exemplarily illustrates a change in threshold voltage after data programming.

FIG. 18 is a flowchart of a method for processing data in a memory according to an aspect of the present invention.

FIG. 19 is a flowchart of a method for processing data in a memory according to another aspect of the present invention.

### BEST MODE

Various aspects are now described with reference to the drawings and like reference numerals are generally used to designate like elements. In the following exemplary embodiments, for description, multiple specific detailed matters are presented to provide general understanding of one or more aspects. However, it will be apparent that the aspects can be implemented without the detailed matters.

Various aspects of the disclosed contents will be described below. The descriptions in the present specification may be implemented in broad forms. Further, it is apparent that a predetermined specific structure, functionality, or both of them disclosed herein are just representative. Based on the description in the present specification, those skilled in the art should recognize that the aspect disclosed herein can be implemented independently from other predetermined aspects and two or more aspects among the aspects can be combined by various methods. For example, an apparatus can be implemented or a method can be executed by using aspects of a predetermined number presented herein. Further, the apparatus can be implemented or the method can be executed by using other structures, functionalities, or structures other than or in addition to those of one or more aspects among the aspects presented herein. Moreover, an aspect of the present invention may include at least one element of claims.

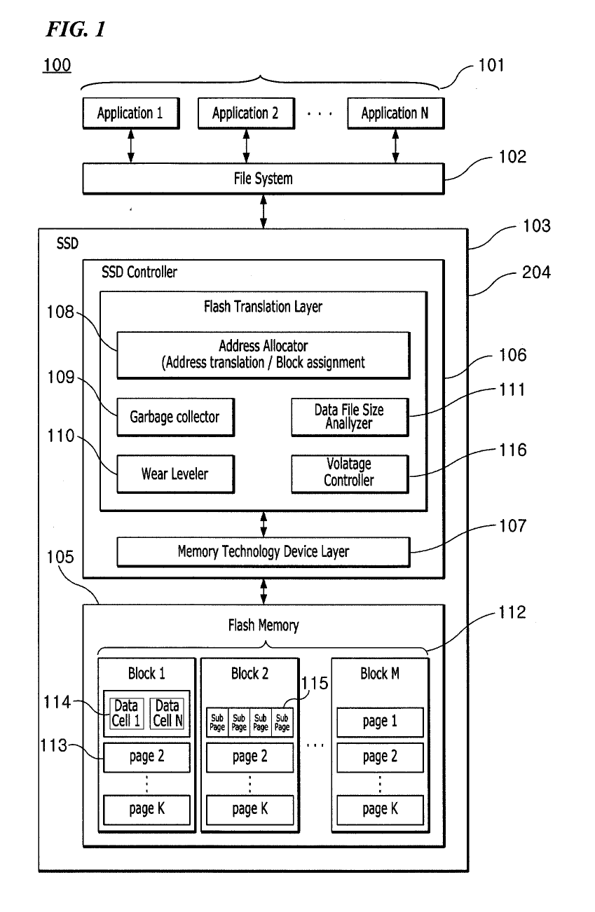

FIG. 1 is a diagram schematically illustrating a memory system 100 according to an aspect of the present invention.

The present specification exemplarily discloses a flash memory, but other memory devices (for example, volatile memories) other than the flash memory (that is, non-volatile memory) may also be included in the scope of the preset invention.

In FIG. 1, the memory system 100 may be largely constituted by an application 101 (alternatively, host), a file system 102, and an SSD 103. Components in FIG. 1 are just examples and some of the components in FIG. 1 may be omitted or components other than the components in FIG. 1 may be included in the memory system 100. Additionally, the SSD 103 in FIG. 1 may be substituted with a memory and a memory controller capable of performing similar functions.

In one aspect of the present invention, applications 1 to N 101 may include a predetermined device or program requiring data storage to the flash memory device such as the SSD.

In one aspect of the present invention, the file system 102 may be designated as the host or an application area together with the application 101. The file system 102 may access predetermined data of the SSD through a logical sector address. In this case, a flash translation layer 106 of an SSD controller 104translates the logical sector address into a physical address to map the logical sector address onto the physical address. Additionally, the file system 102 may represent a virtual sector implemented by the flash translation layer 106. Further, the file system 102 in the present specification may be used to be exchanged with the application 201.

Due to a physical characteristic of the flash memory 105, separate management of a read/write/erase operation is required to use the flash memory 105 like a hard disk. The flash translation layer 106 may represent system software developed for such a purpose. The flash translation layer 106 may include a mapping algorithm translating the logical address into the physical address, an algorithm for determining a data file size, an algorithm for performing wear leveling, an algorithm for controlling voltage to be applied to the flash memory 105, and the like.

In one aspect of the present invention, the flash translation layer 106 of the SSD controller 104 may include an address allocator 108 for mapping the logical address and the physical address, a wear leveler 110 for performing the wear leveling, a garbage collector 109, a data file size analyzer 111 for analyzing and comparing the size of a data file, and a voltage controller 116 for controlling voltage to be applied to the flash memory 105. Additionally, the components of the flash translation layer 106 are just examples and additionally components may be included in the flash translation layer 106 or some of the components may be omitted.

The wear leveler 110 may perform the wear leveling in a block, a page, and/or a bit, in order to increase the lifespan of the flash memory 105.

The garbage collector 109 performs an operation of marking unnecessary data (invalid data or obsolete data), a copy back operation to another block, page, and/or bit, and an operation of erasing the unnecessary data by a block at one time to implement the wear leveling. Therefore, data inserted into an appropriate physical block location, a page location, and/or a bit position may be allocated in order to implement the wear leveling.

Additionally, the address allocator 108 may create a mapping table for mapping bits inserted into memory cells (for example, MLC, TLC, and the like) having a plurality of voltage state levels to appropriate voltage state levels, and the like.

The address allocator 108 may implement allocation of the logical address and the physical address in the block, page, or bit (cell) wise of the memory.

The voltage controller 116 may, for example, apply to the memory cell a driving voltage level having a value equal to or higher than that of a previous in-cell write mode in order to express one or more bits. The application of the voltage may be performed based on the mapping table created by the address allocator 108. Further, the voltage controller 116 checks a voltage level of the memory cell corresponding to one or more bits written in the previous memory cell to decide a driving voltage level value to be applied to the memory cell. Herein, the in-cell write mode may indicate a value to count the number of in-cell write times in one erase cycle (alternatively, erase count).

The data file size analyzer 111 may determine the size of the inserted data file. Through the determination, the data file size analyzer 111 may, for example, determine whether the inserted data file has a smaller size than divided subpages.

Although not illustrated in FIG. 1, the SSD controller 104 may include a programming module (write and erase) and a reading module for writing, erasing, and reading data with respect to the flash memory 105.

The SSD controller 104 may control all operations of the SSD. The SSD controller 104 may receive the logical address from the application 101 or the file system 102. The flash translation layer 106 of the SSD controller 104 may translate the received logical address into the physical address. The translated physical address may be transferred to a memory technology device layer 107 or the flash memory 105. The memory technology device layer 107 may represent an interface layer for supporting various flash memories or RAMs. Additionally, the memory technology device layer 107 may be an optional component.

The flash memory 105 may be constituted by a plurality of memory cells having a string structure as well known to those skilled in the art. An aggregate of the memory cells is generally designated as a cell array. The cell array of the flash memory 105 is constituted by a plurality of memory blocks. Each of the memory blocks 112 is constituted by a plurality of pages 113. Each page is constituted by a plurality of memory cells or data cells 114 sharing one word line. Herein, single bit data, multiple bit data, or triple bit data may be stored in one memory cell or data cell 114. The memory cell in which the single bit data may be stored is designated as a single level cell (SLC), a memory cell in which the multi bit data may be stored is designated as a multi level cell (MLC), and a memory cell in which the triple bit data may be stored are designated as a triple level cell (TLC).

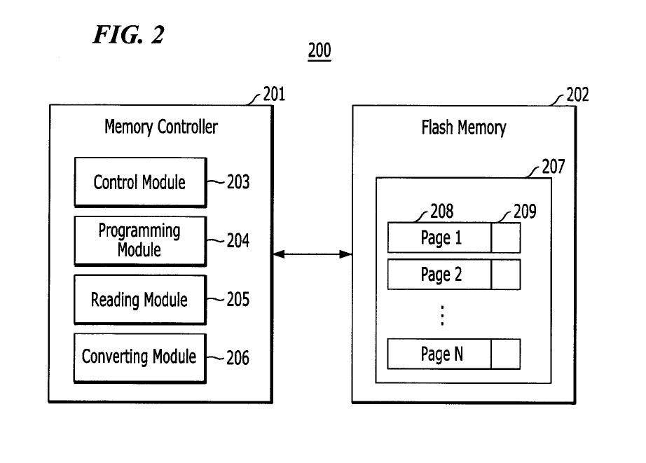

FIG. 2 is a diagram schematically illustrating a memory system 200 according to an aspect of the present invention.

As illustrated in FIG. 2, the memory system 200 may include a memory controller 201 and a flash memory 202.

The memory controller 201 may control all operations of the flash memory 202. The memory controller 201 may include a control module 203 for performing wear leveling, bit allocation, voltage control, and page division, a programming module 204 for performing the write and erase operations, a reading module 205 for performing the read operation, and a converting module 206 for performing an operation of combining the data to convert the data to another address.

In one aspect of the present invention, the control module 203 may perform the wear leveling, the bit allocation, the voltage control, and the page division based on meta data stored in a meta area 306, and the like when receiving an operation request for the flash memory 202 from the host or application.

The control module 203 may control operations of the programming module 204 and the reading module 205.

In an aspect of the present invention, the control module 203 may determine an in-cell write mode or an in-page write modebased on the number of data write request times for the memory cell. The control module 203 may determine a driving voltage level value to be applied in order to express one or more bits in the memory cell based on the determined write mode. Further, the control module 203 may create a mapping table in which one or more bits are mapped to a higher or equivalent level state from low state levels among state levels of the memory cell according to the write mode. The created mapping table may be stored in the flash memory 202 (for example, the meta area).

Wear leveling according to an additional aspect of the present invention may represent not inter-page wear leveling but in-page wear leveling or micro wear leveling. In more detail, there are many cases in which bad blocks are generally generated by not a group of cells in the page but one or more cells are more than an abrasion threshold. Accordingly, in order to implement wear leveling in the cell (that is, in the bit level), the control module 203 may perform a change (for example, shift (alternatively, rotating, reversing, and/or scrambling)) of a bit position in the page or a change (for example, inversion) of a data value written in the bit position in the page.

Additionally, the control module 203 may determine a type of data to be written and determine a technique for writing respective data bits in one page based on the determineed data type. In more detail, the control module 203 may determine the type (for example, file type (doc, xls, ppt, txt, pdf, way, mp3, jpg, zip, and avi)) of the data to be written. Information regarding the file type may be included in the writing request of the data, and the like. When the type of data to be written is determineed, the control module 203 may select an appropriate technique among the micro wear leveling techniques (shifting, reversing, scrambling, and inversing) according to the decided data type, or determine whether to divide the subpages, the number of subpages to be divided, or an allocation technique of one or more bits depending on the state levels of the memory cell, based on a predetermined algorithm.

The control module 203 may be implemented as firmware. For example, the ware control module 203 may be included in the flash translation layer (FTL). Herein, the flash translation layer is the system software that manages the erase/write/read operation in order to use the flash memory 202 like the hard disk as described above. The flash translation layer may perform voltage control, mapping information management, bad block management, data preservation management in unexpected power interruption, abrasion level management, and the like.

The programming module 204 may write the data bits to be written in one page according to control of the control module 201. In more detail, the programming module 204 may apply the driving voltage level value for expressing one or more bits in the memory cell according to a voltage value determined by the control module 201. Further, the programming module 204 may sequentially write data in the pages 208 configuring the block 207. Additionally, the programming module 204 may perform the erase operation of the memory cell in response to a subsequent writing request when all of a plurality of state levels of the memory cell are used. Further, the programming module 204 may perform the erase operation of the memory cell in response to the subsequent writing request when all subpages in the page are used.

Additionally, the programming module 204 may write data in a user area of the flash memory 202 or erase data from the user area. When the write and/or erase operation is performed, the programming module 204 may change the meta data (for example, in-cell write information, erase count or write mode count) stored in the meta area 206 of the flash memory 202.

According to an aspect of the present invention, the programming module 204 may sequentially allocate difference data corresponding to a difference generated by comparing data of the previous file and data of the current file to data of an original file allocated in the page 208 by a file auto save function to be described below. Further, the page 208 may include a spare area 209 and also allocate the difference data to the spare area 209 by the programming module 204.

Additionally, when the data corresponding to the difference between the data is not discovered any longer by comparing the data of the previous file and the data of the current file for the file auto save, the programming module 204 may insert and/or add the difference data corresponding to the difference to the data of the original data in order to generate the data corresponding to the final file and allocate data of the final file generated by the data different from the data of the original file to a new page 208 assigned with a new address.

In an aspect of the present invention, the reading module 205 may read the data written in the user area of the flash memory 202. The reading module 205 may read the data written in the user area based on mapping information between the logical address and the physical address by referring to the data stored in the meta area. In more detail, the reading module 205 may analyze information read from the physical address as an appropriate logical address by referring to the write mode count, the write mode information, the voltage state level of the memory cell, the mapping information, and/or count information stored in the meta area.

In an aspect of the present invention, the meta area may store the meta data (alternatively, control data) for managing the flash memory 202. The meta data may include write mode information, write mode count information, a mapping table, and the like. The meta area may include one or more physical blocks constituted by a plurality of physical pages having a plurality of memory cells.

The meta data may include difference data representing a difference by a comparison of the data of the original file and the data of the current file generated by the file auto save function, the write mode information, the write mode count information, the mapping table, and the like.

Additionally, the meta area may also be integrated in the user area. In this case, for example, the meta data such as the write mode information and/or the count information will be stored in a page or a block in the user area.

Additionally, the meta data may be stored in a header (not illustrated) of the page or the block of the user area.

The user area may represent a data storage of a general flash memory. The user area may include one or more physical blocks constituted by a plurality of physical pages having a plurality of cells.

In one aspect of the present invention, a page 113 in the block 112 in the flash memory 105 may be constituted by a plurality of data cells and the data may be sequentially stored in the plurality of cells. For example, when a size of one page is 4 KB and a size of the current original file is 2 KB, the data may be sequentially added from a next data cell to 2 KB in a physical order of the memory cell in response to the subsequent storage for the same data.

In an aspect of the present invention, one page in the user area of the flash memory 202 may include a plurality of memory cells. Each of the memory cells may express three or more different states according to a driving voltage level value. For example, when the memory cell is an MLC, the memory cell may express four different states. Further, when the memory cell is a TLC, the memory cell may express eight different states.

In an aspect of the present invention, the reading module 205 may read the data stored in the flash memory. Additionally, the reading module 205 may also read different data in a comparison of the data of the previous file and the data of the current file which are sequentially allocated in the page 208 during the file auto save to be described below.

As described above, the programming module 204 may generate data of a file which is adjusted by inserting and/or adding different data to the original data while generating the data of the final file for the file auto save. In the process, the reading module 205 may read the data of the original file stored in the page 208 and the difference data corresponding to the difference between the data of the previous file and the data of the current file which are sequentially stored in the page 208.

The converting module 206 may generate data of the adjusted file by the different data corresponding to the difference between the data of the previous file and the data of the current file and the data of the original file during the file auto save and convert the data of the final file in the new page 208 assigned with the new address.

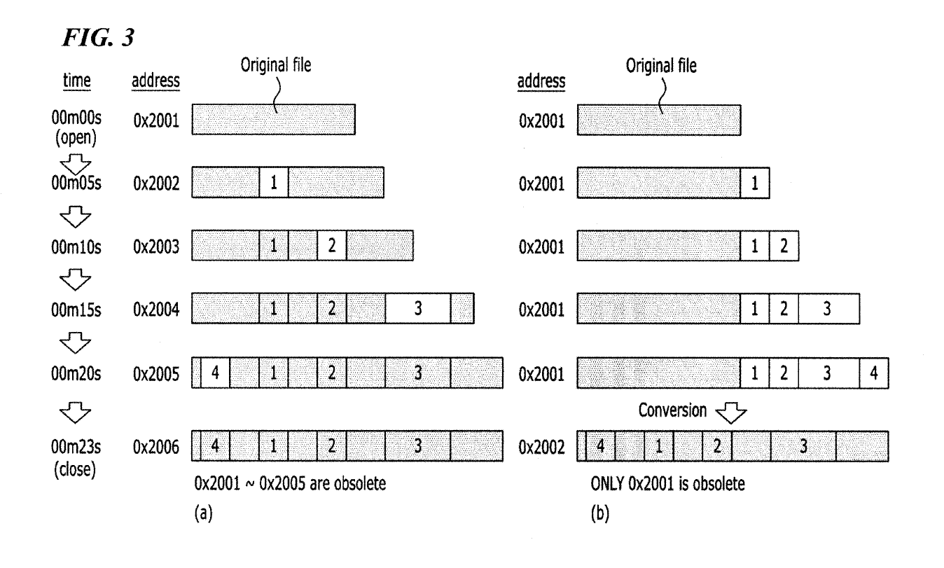

In detail, the converting module 206 may determine and/or decide that the different data according to a comparison of the data of the previous file and the data of the current file is no longer generated. Accordingly, in order to store the data corresponding to the final file in the flash memory, a plurality of different data which is sequentially stored may be added and/or inserted and edited to the original file data and converted to the new address in the flash memory (for example, converted from 0x2001 to 0x2002 as illustrated in FIG. 3).

Alternatively, the converting module 206 may perform the converting operation illustrated in FIG. 3 in response to a file close request. For example, when the application 101 forcibly ends by the user, the application 101 may perform the file close request and the converting module 206 may automatically perform the converting operation illustrated in FIG. 3 in response to the file close request. The converting operation may be automatically performed according to a predetermined number of storing times (for example, storing 10 times), a predetermined time (for example, 30 minutes), and the like in addition to the file close request.

FIG. 3 illustrates a file auto save method with time in the memory system according to an exemplary embodiment of the present invention.

The memory system according to the present invention illustrated in FIG. 3 proposes a technical feature in which the different data representing the difference generated by comparing the data of the original file and/or the data of the previous file and the data of the current file according to the file auto save may be stored and/or added sequentially from the next cell to the data of the original file which is physically stored in the same page.

As illustrated in FIG. 3, a file auto save method in a memory system in the related art includes a technical feature in which the user using the application 101 adjusts the data of the original file for a first period to convert, allocate, and/or store the entire changed data to the page of the new address in the flash memory, according to a predetermined auto save period. Thereafter, even for a second period to an n-th period, the data representing the difference by comparing the previous data through the above method is added and/or changed to the page assigned with the new address, and thus, the memory system in the related art has difficulty in efficiently managing the memory. Accordingly, there is a problem in that an abrasion level of the non-volatile memory system (for example, the flash memory) is increased and thus the lifespan of the memory system is shortened. Furthermore, in the technique in the related art, whenever the data is adjusted, there may be inconvenience that the adjusted data needs to be converted to a proper position of the new page.

However, in the technical feature of an aspect of the present invention illustrated in FIG. 3, until adjusting and/or changing the original data of the application 101 user ends, the different data representing the difference by comparing the previous data by the adjusting and/or the change may be stored in the same page assigned with the same address in which the data of the original file is allocated and/or stored. Accordingly, the respective different data may be edited and converted to the final file data to be allocated to the new page assigned with the new address.

Referring to FIG. 3, the data of the original file may be stored and/or allocated to the page assigned with the address of 0x2001 in the flash memory. The user of the application 101 may adjust the data of the original file within the predetermined period (for example, 5 seconds) by the file auto save function and as a result, in the flash memory, the operation of adding the adjusted data may be required.

For example, in the memory system of FIG. 3, unlike the conventional memory system in which the entire adjusted file data is allocated to the new address, when the user adjusts the data of the original file within the first period, only the first difference data corresponding to the difference of the data may be sequentially allocated and/or stored in the same page of the same address of 0x2001 in which the data of the original file is stored, by comparing the data of the original file and the data of the adjusted file within the first period.

A position in the same page in which the data is additionally stored may also be a position of the spare area 209 which is pre-allocated in the corresponding page.

Thereafter, in the memory system, when the user adjusts the data of the original file and the first different data within the second period, by comparing the data of the original file, the first different data, and the data of the file adjusted within the second period, only the second different data corresponding to the difference of the data may be allocated and/or stored sequentially to the same page of the same address of 0x2001 in which the data of the original file and the first different data are stored.

In the same process, when 20 seconds corresponding to a fourth period are reached, the third different data and the fourth different data illustrated in FIG. 3 may be allocated and/or stored sequentially to the same page of the same address of 0x2001 in which the data of the original file and the first different data are stored.

In the memory system, for example, when the different data corresponding to the difference between the data of the previous file and the data of the current file is no longer detected according to the file auto save period, the comparison and detection operation with the data of the previous file may end. Thereafter, the operation of inserting and/or converting the first different data to the fourth different data to the data of the original file may be performed so that the data of the original file may coincide with the adjusted and/or edited data of the final file. Simultaneously or subsequently, the converted data of the final file may be stored in the new page corresponding to the new address of 0x2002.

Additionally, when the memory system ends by the user or the application 101 after the predetermined period elapses, the comparison and detection operation with the data of the previous file may end. Thereafter, the operation of inserting and/or converting the different data generated during the period to the data of the original file may be performed so that the data of the original file may coincide with the adjusted and/or edited data of the final file. Simultaneously or subsequently, the converted data of the final file may be stored in the new page corresponding to the new address.

In an additional aspect of the present invention, each page 113 in the block 112 in the flash memory 105 may be constituted by a plurality of subpages. For example, when the size of the page 113 is 4 KB, four subpages with a unit of 1 KB may be formed in one page 113. Accordingly, when the plurality of subpages is present, newly stored additional data may be sequentially stored according to the number of subpages.

Unlike the memory system in the related art, the memory system may efficiently manage the flash memory, not waste the new page, achieve the effect of the wear leveling, and finally extend the lifespan of the flash memory.

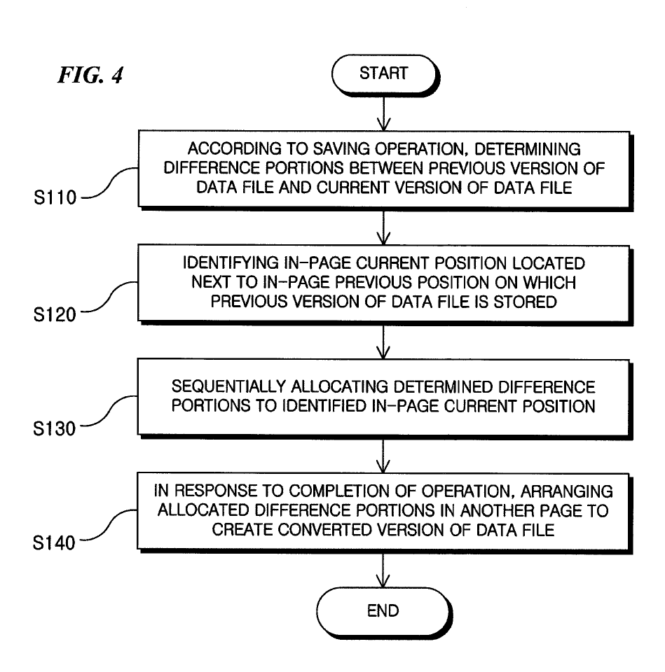

The technical feature illustrated in FIG. 3 will be described below in detail together with the step of processing the data during the file auto save illustrated in FIG. 4.

FIG. 4 illustrates a flowchart for a step of processing data during the file auto save in the memory system according to the aspect of the present invention.

The memory system 200 may perform an operation of determining the changed data portion by comparing the previous version of data file and the current version of data file in response to the data file auto save request by the application 101.

When the file is adjusted and/or changed by the user of the application 101, the data of the adjusted and/or changed portion in the file may be stored in the flash memory 202 according to a predetermined time by the file auto save function which is provided by the memory system 200.

In this case, the memory system 200 may compare the previous version of file data and the current version of file data and decide and determine the data part corresponding to the difference between the previous version of data file and the current version of data file which is adjusted and/or changed by the user (S120).

According to an aspect of the present invention, the data part corresponding to the difference may be periodically determined according to the predetermined time for the file auto save, and a plurality of data parts corresponding to the difference for the file auto save may be present according to the period.

The memory system 200 may identify, after determining the changed data (S110), an in-page 208 area in which the previous version of data file is stored and a current save area of the data to be stored later in the in-page area (S120).

In detail, the memory system 200 may identify the current save area in which the data corresponding to the difference is allocated, in order to store the different data determined for the file auto save in the same in-page area later.

Thereafter, the memory system 200 may allocate and/or store the data part corresponding to the difference between the previous version of data file and the current version of data file in the current save area in the in-page area in sequence (S130).

As illustrated in FIG. 3, the data of the original file corresponding to the previous version of data file is allocated to one page assigned with the address of 0x2001, and the data part corresponding to the difference between the previous version of data file and the current version of data file is sequentially stored in the same page assigned with the address of 0x2001 in the flash memory according to the trend of the auto save time for the file auto save.

In more detail, the memory system 200 may generate the first different data to the fourth different data according to the predetermined auto save time, for example, when four periods elapse. The different data may be sequentially stored in the same page in the flash memory. In more detail, the memory system 200 may sequentially store the data corresponding to the adjusted difference by comparing the previous data in the same page, instead of inserting the difference data to the original data every period of the auto save time to store the different data in the new different address.

According to an aspect of the present invention, the memory system 200 may determine that the difference data according to a comparison of the data of the previous file and the data of the current file is no longer generated. Alternatively, the memory system 200 may receive the file end request from the application. Alternatively, the memory system 200 may determine that the predetermined time period elapses or the auto save is performed the predetermined number of times. Accordingly, the memory system 200 may convert the original file data to the final version of file by allocating the new address in the flash memory to insert the plurality of sequentially stored different data to a proper position of the original file data in order to store the data corresponding to the final file in the flash memory (for example, conversion from 0x2001 to 0x2002 as illustrated in FIG. 3) (S140).

As described above, the memory system 200 may generate the difference data periodically according to the predetermined auto save time (for example, 5 seconds) of the file auto save function. As a result, the memory system 200 may generate the plurality of difference data.

The file auto save function in the flash memory in the related art has a problem in that when due to the characteristic of the flash memory, the data is adjusted and/or edited by the user using the application 101, the adjusted and/or edited data inserted to the previous data may not be stored in the same page in the flash memory. Accordingly, whenever the file auto save function is executed, the edited data adjusted and/or added to the previous data is allocated to and stored in the new page address in the flash memory.

However, according to the steps S110 to S140 illustrated in FIG. 4, in the page to be allocated to one address, the difference data corresponding to the difference between the previous file data and the current file data may be sequentially stored. In the process of generating the final file data, the difference data is edited and/or converted to the new address to implement the wear leveling in the memory. Accordingly, the flash memory is efficiently managed and thus the lifespan of the flash memory may be increased.

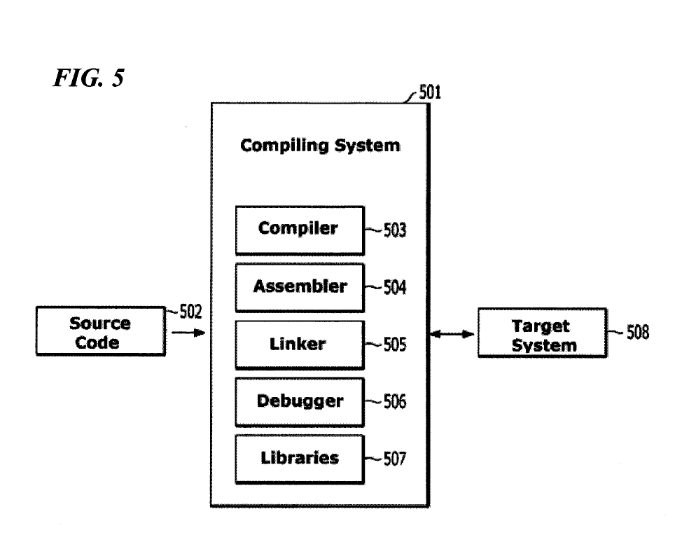

FIG. 5 illustrates a process of allocating data to a target system through a compiling system from a source code as components according to an exemplary embodiment of the present invention.

According to an exemplary embodiment of the present invention, a compiling system 501 may communicate with a file generating the source code 502 and a target system 508.

As illustrated in FIG. 5, the compiling system 501 may include a compiler 503, an assembler 504, a linker 505, a debugger 506, and libraries 507. The components illustrated in FIG. 5 are just exemplified, and additional components may be present or some of the components illustrated in FIG. 5 may be omitted. The compiling system 501 may represent a set of programming tools for generating programs suitable for the target system 508. Compilation performed in the compiling system 501 may include online compilation and/or offline compilation.

The compiling system 501 may be referred to as a tool chain. In more detail, the output of the respective components of the compiling system 501 may be used as the input of the different component.

The compiling system 501 may be replaced with the compiler 503. In this case, the compiler 503 may represent an upper concept which is collectively referred to as the assembler 504, the linker 505, the debugger 506, and the libraries 507.

In an aspect of the present invention, the target system 508 may include for example, a CPU/processor. The target system 508 may represent a system for actually performing application software.

In an aspect of the present invention, the source code 502 may represent codes constituted by various languages including, for example, a C code. The source code 502 may be generated by a host system (not illustrated) developing the application software.

The compiler 503, the assembler 504, and the linker 505 may convert the source code to a program which is executable on the target system 508. An object file may be generated through the compiler 503 and the assembler 504. Further, the linker 505 may convert the object file to the program file. In the conversion process of the linker, interface data related with the target system 508 stored in the libraries 507 may be considered. The libraries 507 may include an interface for the target system 508. The debugger 506 may perform debugging for the generated program file.

The compiling system 501 may convert the source code to a machine language code suitable for the target system. The compiling system 501 may detect data to be allocated to the register of the target system 508 from the source code, generate correlation information representing correlation between the data stored in each of one or more registers and the data to be allocated, and determine a target register to allocate the data to be allocated among the registers based on the correlation information. Further, the compiling system 501 may also allocate the data to be allocated to the determined target register.

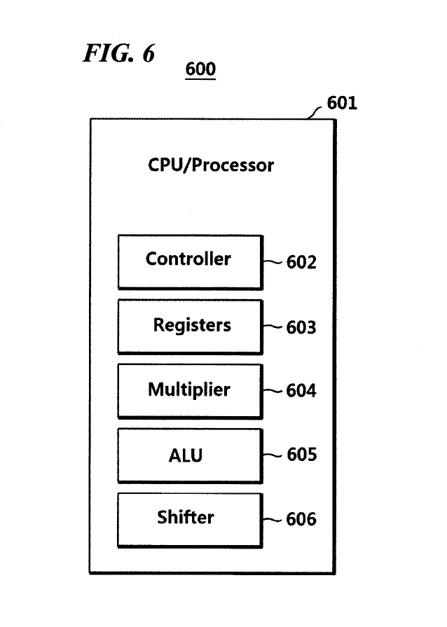

FIG. 6 schematically illustrates a target system 600 according to an exemplary embodiment of the present invention.

In this specification, a CPU and a processor may be interchangeably used.

As illustrated in FIG. 6, a processor 601 according to an aspect of the present invention may include a controller 602, a register(s) 603, a multiplayer 604, an arithmetic and logic unit (ALU) 605, and a shifter 606. The components illustrated in FIG. 6 are just exemplified, and additional components may be present or some of the components illustrated in FIG. 6 may be omitted.

The processor 601 may include a volatile processor and/or a non-volatile processor.

The controller 602 may control the overall operation of the processor 601.

In an aspect of the present invention, the controller 602 may receive a machine language code (that is, compiled data) compiled from the compiling system.

In an additional aspect of the present invention, the controller 602 may also compile the source code to the machine language code. When the controller 602 performs the compiling, the controller 602 may perform operations of retrieving registers in which the data are currently stored and allocating the data to the searched register.

Although not illustrated in FIG. 6, the controller 602 may include a wear level detection module and an allocation module. Further, hereinafter, operations of the controller 602 to be described below may be implemented by the compiling system 501 or the compiler 503 of FIG. 5.

The wear level detection module may write the number of usage times of each register 603 of the processor 601 and perform a wear leveling operation. In the register 603 of the non-volatile processor 601, the number of overwrite times may be limited. Accordingly, in order to increase the lifespan of the register, when the data is written in the register, the controller 602 needs to prevent only the specific register of the processor 601 (alternatively, a specific memory cell in the specific register) from being repetitively used. Therefore, the wear level detection module may perform a wear leveling operation to evenly use all the registers. The wear level detection module may write and manage the total number of times of rewrite operation which is performed for every register of the processor 601.

In an additional aspect of the present invention, when the new data is written from the host system, the wear level detection module may convert a mapping table of a logic address and a physical address so that the corresponding data is written in the appropriate register for permitting all of the registers to be evenly used by referring to the number of times of the rewrite operation of all of the registers of the processor 601.

The controller 602 may detect the data to be allocated to the register from the source code according to the exemplary embodiment of the present invention. Further, the controller 602 may generate correlation information indicating correlation between the data stored in each of the one or more registers and the data to be allocated. The correlation information may indicate similarity of the data to be allocated and the data stored in the register. The similarity may represent for example, similarity of data in a bit unit.

In order to generate the correlation information, the controller 602 configures a virtual processor to read values of the data which are currently stored in each of one or more registers on the virtual processor. In this case, the controller 602 may generate the correlation information by comparing the values of the read data and the values of the data detected from the source code.

Further, the controller 602 may determine a target register to allocate the data among the registers 603 based on the correlation information. Next, the controller 602 may allocate the data to be allocated to the determined target register.

The controller 602 may determine the least used register as the target register when the target register having a correlation of a predetermined correlation or more with the data to be allocated is not determined. The operation of the controller may be implemented by using the aforementioned wear leveling module.

The controller 602 may search a register in which data with the highest correlation with the data to be allocated to the register from the source code are currently stored, based on the correlation information. That is, the controller 602 may determine a register in which the data with the highest correlation with the data to be allocated are currently stored among the registers as the target register, based on the correlation information.

According to an exemplary embodiment of the present invention, the controller 602 may allocate the data to be allocated in the searched register without rewrite, when the correlation between the data to be allocated and the data stored in the searched register is the predetermined correlation or more (for example, both data are the same as each other).

In an aspect of the present invention, for example, in the case where the input of 8 bits is inserted, when pre-stored data having bits (for example, 5 bits) with a matching value of a predetermined ratio (for example, 60%) or more is present, it may be determined that both data have the predetermined correlation. The aforementioned ratio is just exemplified and various methods of determining correlation between the data may be present.

The registers searched by the aforementioned operations may include an invalid page (an obsolete page or a garbage page) in which old version of data is stored or a valid page in which current version of data is stored.

The allocation module of the controller 602 may allocate the data generated in the compiler to the register 603. Further, the allocation module may allocate the data to the searched register (that is, the target register) according to the exemplary embodiment of the present invention. When the compiler allocates the data to the register 603, according to the exemplary embodiment of the present invention, the complier may allocate the data to the register (that is, the target register) by retrieving the register in which the data with high correlation with the data to be allocated is currently stored. In this case, when the correlation between the data to be allocated and the currently stored data has a predetermined level or more (for example, the same data), the corresponding data is allocated to the corresponding register without rewrite to increase the lifespan of the register. Furthermore, when the data to be allocated is allocated, written, and stored in the register in which the data having the correlation of the predetermined level or more with the data to be allocated is stored, the rewrite amount of the data may be reduced, and thus, the wear leveling effect may be achieved.

The controller 602 may allocate the data to the least used register, when the data stored in the register which has the correlation of the predetermined correlation or more with the data to be allocated is not present. Further, the controller 602 may allocate the data to the least used register at least partially based on the number of use times of the register written by the wear leveling module. Accordingly, the use amount of the register may be set so as not to be biased to the specific register.

In an aspect of the present invention, the multiplier 604, the ALU 605, and the shifter 606 may perform processes related with arithmetic, mathematics, logic, and the like. For example, the multiplier 604 obtains values from two registers to multiply the obtained values and store result values in another register. Further, for example, the ALU 605 may perform operations such as addition, subtraction, absolute value operations, logic operations (AND, OR, XOR and NOT), and conversion. Furthermore, for example, the shifter 606 may perform a binary operation such as shifting and rotating.

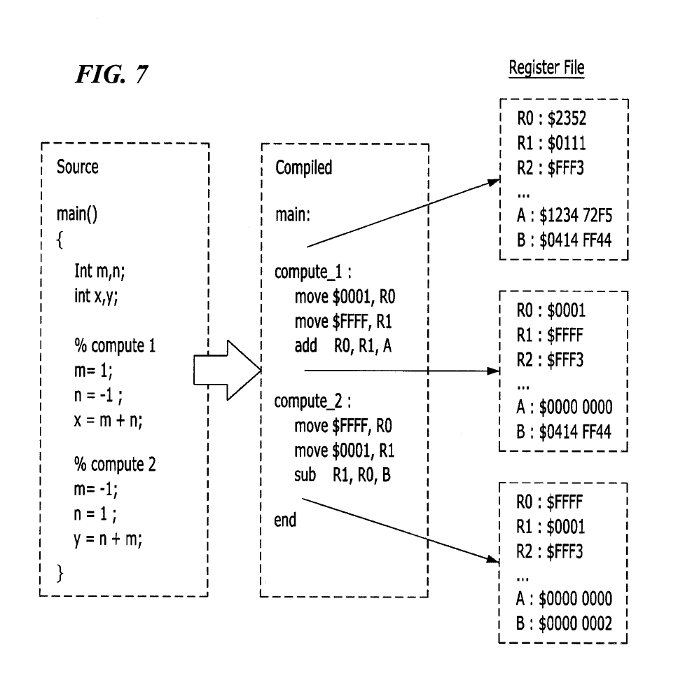

FIG. 7 illustrates an example in which an existing compiler allocates data to a register.

FIG. 7 illustrates an example of an assembly code or a machine language code which is compiled by the existing compiler. In the example, the value of the register may be changed when the code operates in the processor.

The code in the example illustrated in FIG. 7 is related with the simple mathematics, and calculation 1 calculates 1+(−1) to store the result and calculation 2 calculates 1−(−1) to store the result. In the case of being compiled in the compiler, respective integers (1, −1) variables m and n are mapped in the register.

In the method in the related art, the data are mapped in the randomly selected registers. Accordingly, in calculation 1, m is mapped to register R0 and n is mapped to register R1, respectively. For example, the registers may be universal registers.

The given data (constants) of 1($0001) and −1($FFFF) are allocated to R0 and R1, respectively. The allocation is performed by a move operation in FIG. 7. In addition, the addition operation of R0 and R1 is performed and the result may be written in an accumulator (ALU) A. The accumulator A may also be pre-allocated to the specific region of the register.

When performing calculation 2, m is mapped in register R0, n is mapped in register R1, −1($FFFF) is allocated to R0, and 1($0001) is allocated in R1. Accordingly, when calculation 2 is performed, registers R0 and R1 are updated so that m=R0=−1 and n=R1=1 may be mapped, respectively.

In an example illustrated in FIG. 7, the register R0 may be sequentially updated to values of $2352 to $0001 and $FFFF. Further, the register R1 may be sequentially updated to values of $0111 to $FFFF and $0001.

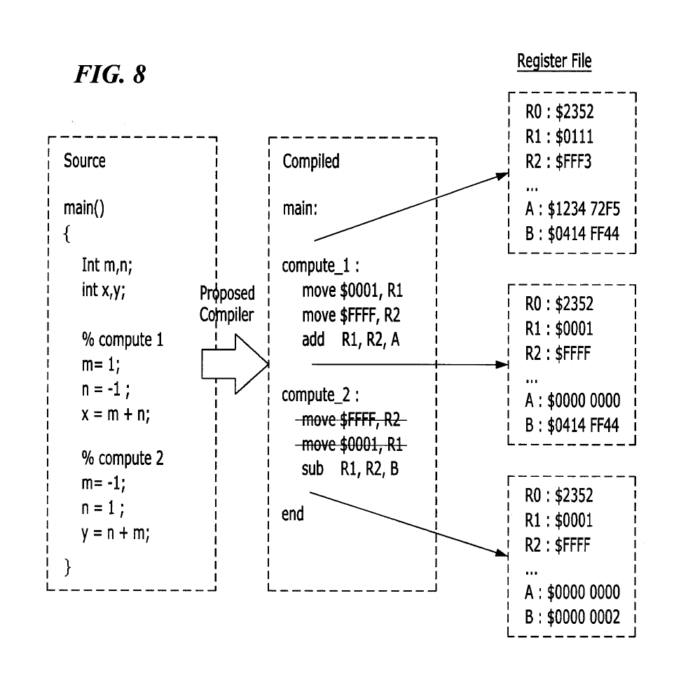

FIG. 8 illustrates an example in which data is allocated to a register according to an exemplary embodiment of the present invention. In the same code as the aforementioned example, the compiler particularly selects the register in which the parameters m and n are mapped. According to the exemplary embodiment of the present invention, the compiler may select the register mapping the parameters.

In calculation 1, m is mapped in R1 where a value $0111 which is closest to (has high correlation with) $0001, which is a value to be allocated among candidate registers, is stored. Further, n is mapped in R2 where the closest value $FFF3 to $FFFF, which is a value to be allocated, is stored. In the mapping process for performing calculation 2, a technical effect by the method according to an aspect of the present invention occurs. In the example of FIG. 6, m and n are mapped in R0 and R1, respectively, to be updated to completely different values.

However, according to the exemplary embodiment of the present invention, the compiler in the example of FIG. 8 proposes the register to be mapped by verifying the previous value of each register to perform an optimizing process of mapping m and R2 and mapping n and R1. Accordingly, in the aforementioned process, each register may not be updated (that is, rewritten). Therefore, the register of the non-volatile processor may not be worn as compared with the existing method in FIG. 6. The aforementioned data and the register mapping are just exemplified and various types of data may be mapped in various types of registers.

When comparing FIGS. 7 and 8, the mapping method illustrated in FIG. 8 may permit, for example, a least register update without increasing the calculation amount of the processor through efficient register mapping of maximizing the lifespan of the non-volatile processor (non-volatile register).

In the aforementioned example, when comparing a case where hexadecimal values are updated by the existing method, in the case of applying the method according to the exemplary embodiment of the present invention, only three values are updated to obtain the same result. Accordingly, in the case of using the method according to the aspect of the present invention, the number of updated times may be reduced and thus the lifespan of the processor may be increased. Furthermore, according to an aspect of the present invention, a need for the move operation in calculation 2 may be removed and the compiler correspondinglyneeds to store two operation cycles.

As described above with reference to FIGS. 5 and 6, the compiler may detect the correlation between the data to be allocated in the register. For example, in FIG. 8, m in calculation 1 and n in calculation 2 may be data having correlation. The correlation may be detected or determined by the compiler (alternatively, the controller). In the process of allocating the data to the register, the compiler may allocate two or more data having a correlation with the predetermined correlation or more among the data to the same register. For example, m in calculation 1 and n in calculation 2 have the same data of 1. Accordingly, m and n may be equally allocated to the register R1. The correlation equal to or higher than the predetermined correlation may represent, for example, a case where both data are the same as each other. The aforementioned data and register are just exemplified and various data may be allocated to various registers. Further, the aforementioned correlation is just exemplified and various types of correlations for efficient compiling may be present. Further, the correlation represents the case where the data are the same as each other, and may represent a case in which predetermined bits or more are the same as each other in a data unit.

In the case where the register in which the data properly matched with the data to be input is stored is not present, the compiler may allocate the data to the least used register for wear leveling. In this case, the compiler may search the least used register at least partially based on the number of use times of the memory written by the wear leveling tool.

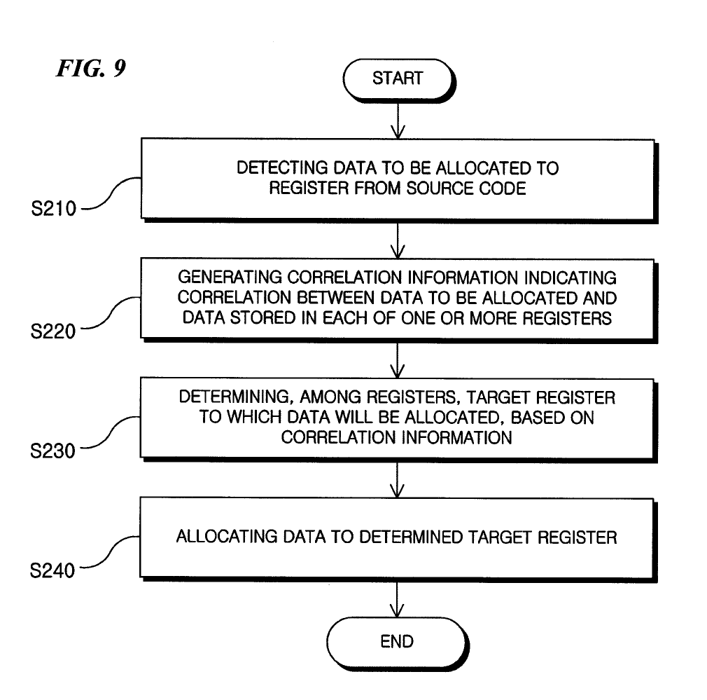

FIG. 9 is a flowchart illustrating a method of allocating data to a register according to an exemplary embodiment of the present invention.

Further, respective steps of the flowchart illustrated in FIG. 9 are not required, and if necessary, some steps may be omitted or added.

As described above, in the NVP paradigm, the registers configuring the non-volatile processor may be formed in a form of the non-volatile memory such as an SSD. For example, in the case of the CPU constituted by the non-volatile processor, since in the register formed by the SSD, writing and overwriting (rewriting) operations of many data are performed, when the wear leveling is not properly performed due to the characteristic of the SSD, there is a problem in the lifespan of the register.

According to the exemplary embodiment of the present invention, the compiler (alternatively, the controller of the processor) may detect the data to be allocated to the registers positioned at the processor or the CPU from the source code (S210). For example, as described with reference to FIG. 8, in calculation 1, 1 to be allocated to m, −1 to be allocated to n, and the like may become the data. The aforementioned data are just exemplified, and the present invention may include all types of data which may be allocated to the register from the compiler.

Additionally, a general compiler allocates the data to the register while compiling, and the compiler according to the exemplary embodiment of the present invention first detects the data to be allocated to the register from the source code to allow the compiler to perform efficient compiling.

According to the exemplary embodiment of the present invention, the compiler may generate correlation information indicating a correlation between the data stored in each of one or more registers and the data to be allocated (S220). In more detail, for example, the correlation information may be generated by a virtual processor to read values of the data which are currently stored in each of one or more registers on the virtual processor and may be generated by comparing the values of the read data and the values of the data detected from the source code. That is, by the aforementioned method, which value is written in the specific register through the previous operation on the source code may be determined.

The compiler may determine a target register to which the data to be allocated among the registers is to be allocated based on the correlation information (S230).

For example, as described with reference to FIG. 8, the compiler according to the exemplary embodiment of the present invention may search the register R1 (that is, the target register) in which $0111 that is the data having the highest correlation with $0001 that is the data to be allocated in calculation 1 is stored. The correlation may be determined through the number of matched bits by comparing the data to be allocated and the data stored in the register. As the bit number by which the data to be allocated and the data stored in the register are matched with each other is increased, the correlation between the data to be allocated and the data stored in the register may be increased.

According to the exemplary embodiment of the present invention, the compiler may allocate the data to be allocated to the determined target register (S240).

For example, as described with reference to FIG. 8, the compiler according to the exemplary embodiment of the present invention may allocate the data to the register R1 (that is, the target register) in which $0111 as the data having the highest correlation with the $0001 data to be allocated is stored.

The compiler may also allocate the data to be allocated to the target register without rewriting when the adjusting between the data to be allocated and the data stored in the target register has a predetermined correlation or more. In more detail, the compiler may allocate the data to be allocated to the searched register without rewrite when the register in which the same value as the data to be allocated is stored is searched. Through the data allocation, the data may be allocated without influencing the number of rewrite times of the register.

The controller may allocate the data to the least used register, when the data stored in the register which has the correlation of the predetermined correlation or more with the data to be allocated is not present. Since the register of the non-volatile processor has a limit to the number of write times, there is a need to evenly use all of the registers. Accordingly, by using the wear leveling module, the number of use times of the register may be written and the data may be allocated from the least used register so that the number of use times of all the registers is uniformly distributed. Therefore, the compiler or the controller may search the least used register at least partially based on the number of use times of the register written by the wear leveling module. The compiler or the controller may allocate the data to the searched register (the target register).

According to another exemplary embodiment of the present invention, the compiler may detect the correlation of the data to be allocated to the register from the source code. The compiler may allocate two or more data having a correlation with the predetermined correlation or more among the data to the same register. As described with reference to FIG. 8, m in calculation 1 and n in calculation 2 may be data having the correlation. In this case, when allocating the data to the register, the compiler may allocate the data to the same register. For example, m in calculation 1 and n in calculation 2 have the same value of 1. Accordingly, the compiler may allocate m and n to the register R1. In this case, the correlation equal to or higher than the predetermined correlation may represent a case where both data are the same as each other. The aforementioned data and register are just exemplified and various data may be allocated to various registers. Further, the aforementioned correlation is just exemplified and various correlations for efficient compiling may be present. Further, the correlation represents the case where the data are the same as each other, and may represent a case where predetermined bits or more are the same as each other in a data unit.

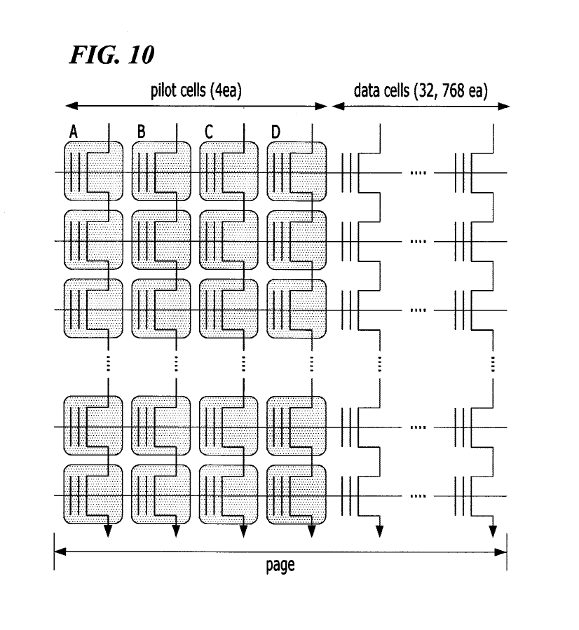

FIG. 10 exemplarily illustrates a data block including pilot cells according to an aspect of the present invention.

As described above, memories such as a flash memory may use arrays of analog memory cells for storing the data. Each analog memory cell may store an amount of analog values such as a charge amount or voltage for expressing information stored in the cell. For example, each memory cell holds a predetermined amount of charge. The range of the analog values may be generally divided into predetermined regions and each region may correspond to one or more data bit values. For example, SLC may be divided into two regions and cells having a plurality of levels such as MLC may be divided into four or more regions.

In the memory such as the SSD, the data may be written in the analog memory by writing a nominal analog value corresponding to required bits. Since the analog values may have various statistic distributions, selection for the nominal values used for programming different levels may have a large effect on performance of the memory cell array.

When the nominal values are adjacent to each other, a probability that the error occurs in reading the memory cell is high. On the contrary, when the nominal values have a large difference, a dynamic range of the analog values in the memory cell array may be increased. In this case, more power may be consumed and the programming speed of the memory cell may be lowered.

Since the nominal values in each cell has an attribute which may be temporally and spatially changed, using a predetermined value in reading and writing may have a bad effect on performance of the memory such as a bit error rate (BER).

When more voltage level states in one cell are present, a probability that the error occurs may be higher due to a characteristic of the analog voltage in writing and reading the data.

In this situation, the present invention proposes a programming method using predetermined nominal values in a pilot cell positioned in a predetermined region of the page. Through the programming method, analog voltages read in the pilot cells may be used for compensating for an error and a change of the voltages in the adjacent data cells.

As illustrated in FIG. 10, one page in the block of the memory according to an aspect of the present invention may be constituted by one or more (for example, four) pilot cells and a plurality of (for example, 32,768) data cells. In FIG. 10, four pilot cells are exemplarily illustrated, but the pilot cells more than or less than the four pilot cells may be included in the scope of the present invention.

In FIG. 10, the SSD constituted by the MLC having four nominal values is exemplified. In each page, four pilot cells represented by A, B, C, and D may be predetermined. With respect to the respective pilot cells, pilot cell A, pilot cell B, pilot cell C, and pilot cell D may be allocated to(with?) 11, 10, 00, and 01, respectively. The pilot cells may have unique nominal values (that is, reference voltage values), respectively.

The nominal values corresponding to the pilot cells A, B, C, and D, respectively are fixed values, differently allocated to each page, or may be changed by various methods in order to implement the wear leveling. Further, the pilot cells A to D may be disposed in various positions in the page. For example, the pilot cells may be positioned in front, in the middle, or at the end of the page. The arrangement of the pilot cells may be determined based on types of pages, a programming count, and a random method.

By using the pilot cells, the data may be programmed by using the predetermined nominal values in the pilot cells arranged at the predetermined position in the page. Next, the reading or writing operation for the data cell may be performed by referring to the values of the pilot cells.

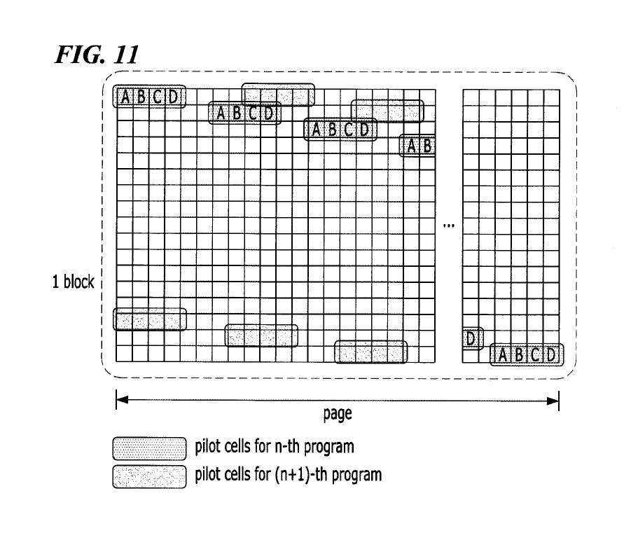

FIG. 11 exemplarily illustrates a change in arrangement of pilot cells according to a programming count and a page according to an aspect of the present invention.

As illustrated in FIG. 11, the pilot cells may be arranged at various positions based on the programming count and/or the page. Through the placement at various positions, the pilot cells may represent more useful values in providing reference to the data cells. Additionally, the placement at various positions may achieve even a wear leveling effect in the page.

According to an aspect of the present invention, the memory controller 201 writes the data by applying the voltage values to the pilot cells and thereafter, reads the pilot cells before writing the data in the data cell or reading the data to determine a voltage value to be used for writing or reading the data in the data cells.

According to an aspect of the present invention, the memory controller 201 may write the values in the pilot cells and thereafter, read the analog voltage values for the pilot cells. In the specification, in general, programming may include a process of re-read voltage for validation.

Instead of the reading process for the validation, more accurate voltage values may be read by using higher resolution than voltage steps used for the programming. For example, when the value of ‘00’ is written in pilot cell D, voltage of 5 V may be written. However, when the corresponding cell is read, voltage of 4.7 V may be read. An opposite situation may also occur.

In this situation, at the programming time in the data areas, the writing operation may be performed by using the calculated nominal values in association with the read voltages in the pilot cells. That is, as described above, when the nominal values in the reading process do not reach the desired reference voltage value (writing 5 V and reading 4.7 V), the voltage (for example, 0.3 V) by a difference between the voltage value when writing and the voltage value when reading may be considered in programming the data cell. That is, the data cell may be written by voltage of 5.3 V when being programmed. In this case, in reading the data cell, when the reference voltage value uses 5 V, more accurate reading may be performed.

On the contrary, when the nominal values in the reading process exceed the desired reference voltage value (writing 5 V and reading 5.3V), the voltage (for example, −0.3V) by a difference between the voltage value while writing and the voltage value while reading may be considered in programming the data cell. That is, the data cell may be written by voltage of 4.7 V when being programmed. In this case, in reading the data cell, when the reference voltage value uses 5 V, more accurate reading may be performed.

The technique may be based on an assumption that sensitivity and responsiveness for voltages of the cells are similar in one page. That is, other variables which influence a wear level, a temperature, and sensitivities of the cells may have a similar characteristic to the programming in the same page. Therefore, an optimal nominal value may be determined and maintained due to programming using the feed-back from the pilot cells. Through the process, since the feed-back from the pilot cells is reflected to perform programming in the programming process, the reading process may be simply performed by using a predetermined reference voltage value without a particular calculating operation.

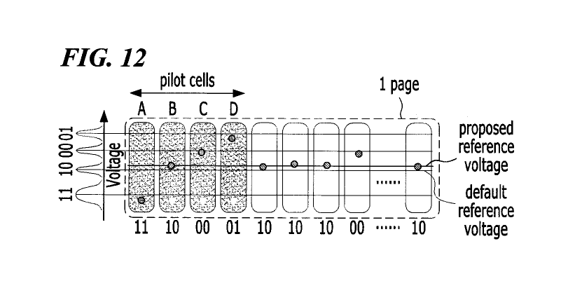

FIG. 12 exemplarily illustrates a reading method using pilot cells in a page according to an aspect of the present invention.

The memory controller 201 may perform programming for a data region by using predetermined nominal values used in the pilot cells without reflecting a feed-back which is referred in the pilot cells. That is, a page including the pilot cells and data cells may be programmed by using the same nominal values which are given. Instead, in a reading process, the memory controller 201 first reads the pilot cells and calculates threshold voltage values to be used for reading the data cells by referring to reading analog voltage values in the pilot cells.

FIG. 12 exemplarily illustrates a process for determining read voltage values for data cells by first referring to the read voltage values of the pilot cells in the reading process.

Respective pilot cells A, B, C, and D may be programmed by using nominal values (reference voltage values) to correspond to ‘11’, ‘10’, ‘00’, and ‘01’, respectively. Voltage values which may be read in the programmed cells are represented by circles in FIG. 12. For example, as illustrated in FIG. 12, in the case of pilot cell A in which the value of ‘11’ is written, the voltage value may be read as a voltage value lower than the reference voltage value. Further, in the case of pilot cell B in which the value of ‘10’ is written, the voltage value may be read as a voltage value higher than the reference voltage value.

The read voltage values for the pilot cells may be used as new reference voltage for the corresponding page. That is, in the case of a voltage level for reading the value of ‘10’, as illustrated in FIG. 12, not a voltage level value (default reference voltage) used in writing the value of ‘10’ but a voltage level value (proposed reference voltage) actually measured in reading pilot cell B may be used as a voltage level value for reading the data cells in the corresponding page.

Therefore, the reading process using the pilot cells in such a scheme may cause less reading errors than the existing reading process.

In an additional aspect of the present invention, the specification presents multiple pilot cells for the nominal values in one block, but alternatively, analog voltage values or nominal values are averaged in a block to be calculated or averaged according to a time to be calculated. Furthermore, since the analog values may be stored in a temporary memory such as a DRAM, a more rapid data access may be achieved.

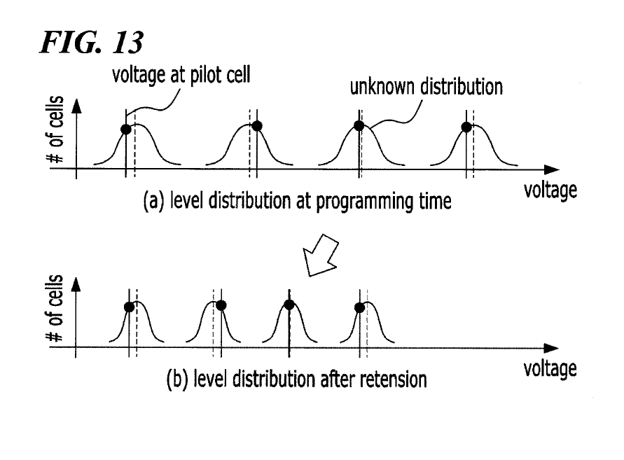

FIG. 13 exemplarily illustrates a change in threshold voltage after data programming.

When a predetermined time elapsed after data is programmed, distribution of the analog voltage values may be changed as illustrated in FIG. 13. In such a situation, a method in which the nominal values are adaptively defined with respect to the respective pages may be considered. Since the method considers different response characteristics of the cells, the method may have an advantage in terms of error occurrence and power consumption.

In more detail, the nominal voltage values may be adaptively selected during the data programming. Next, the voltage values may be stored as parameter to be used for reading the storage. The voltage values need to be stored as different parameter values in the respective pages. However, the parameters may be vast overhead in terms of the storage. That is, a separate vast space for allocating the parameter needs to be provided.

As technical features according to an aspect of the present invention associated with FIGS. 11 and 12, the data for the data cell may be efficiently read by referring to the analog voltage values for the pilot cells without requiring the separate space for storing the parameters.

Therefore, according to an aspect of the present invention, as illustrated in FIG. 13, when a pilot voltage level is determined by previously referring to the pilot cells, an appropriate threshold voltage value may be found without determining the response characteristics of the respective cells even though the voltage level is changed after the data programming. That is, when the pilot cells are used, more robust threshold voltage values may be generated without wasting a storage space.

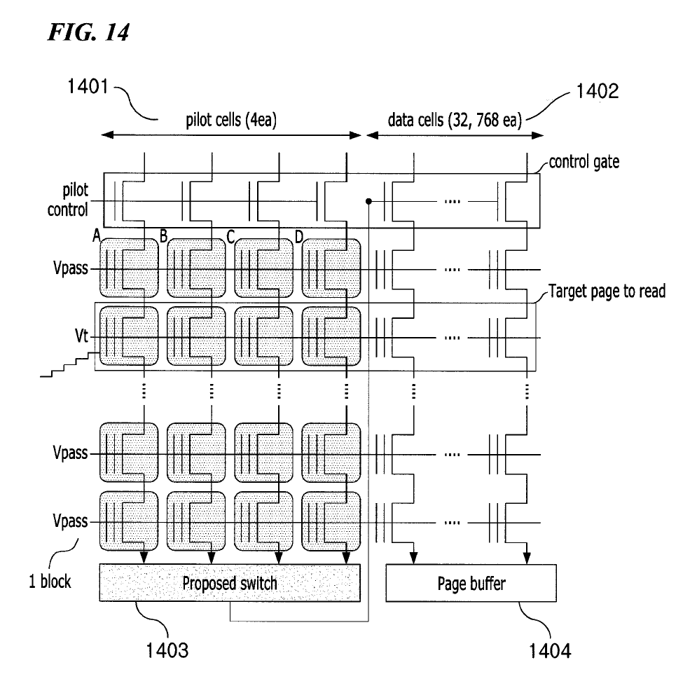

FIG. 14 exemplarily illustrates a voltage reading mechanism using pilot cells according to an aspect of the present invention.

FIG. 14 illustrates a plurality of cell arrays having a plurality of columns and rows of memory cells in one block. The memory cells illustrated in FIG. 14 are connected with each other in a specific array configuration. The array configuration of the memory cells is exemplary and other types of memory cells or other array configurations may also be included in the scope of the present invention.

As described above, a value stored (alternatively, written) in the memory cell may be read by measuring threshold voltage Vt of the cell. The reading threshold voltage may represent the quantity of charges stored in the memory cell.

As illustrated in FIG. 14, for example, one page may include 4 pilot cells 1401 and 32768 data cells 1402. Each of the memory cells includes a floating gate transistor. The pilot cells 1401 and the data cells 1402 (that is, gates of transistors of the cells) in one page share the same word line. Further, sources of transistors in respective columns may be connected to each other by bit lines. In the case of a NOR cell, the source may be directly connected to the bit lines and in the case of a NAND cell, the bit line may be connected to a string of a floating gate.

In FIG. 14, since a case of an MLC is described as an example, 4 different nominal values may be present. 4 different nominal values may be used to be written in pilot cells A, B, C, and D, respectively.

In an aspect of the present invention, an exemplary data block may further include a switch 1403 and/or a page buffer 1404. The switch 1403 may be disposed in a path from drains of the pilot cells to the sources of the data cells.

A target page to be read may be determined to correspond to a data reading request. Step voltage may be applied to the target page to be read. The memory controller 201 or the reading module 205 applies the step voltage to the gate (that is, the word line to which the cell is connected) of the cell to read threshold voltage Vt of a specific memory cell. This may be implemented by checking whether drain current of a specific cell is more than the threshold voltage Vt. That is, the memory controller 201 or the reading module 205 applies the step voltage to the word line which the specific cell accesses to determine a minimum gate voltage value in which the drain current is more than the threshold voltage Vt.

As illustrated in FIG. 14, the memory controller 201 or the reading module 205 applies the step voltage to the word line of the target page to measure reading threshold voltage values of the pilot cells 1401 in the target page. That is, when the threshold voltage Vt corresponding to the pilot cell (for example, pilot cell A) in the target page has exceeded, the switch 1403 is closed, and as a result, current may flow to the data cell 1402 in the corresponding page.

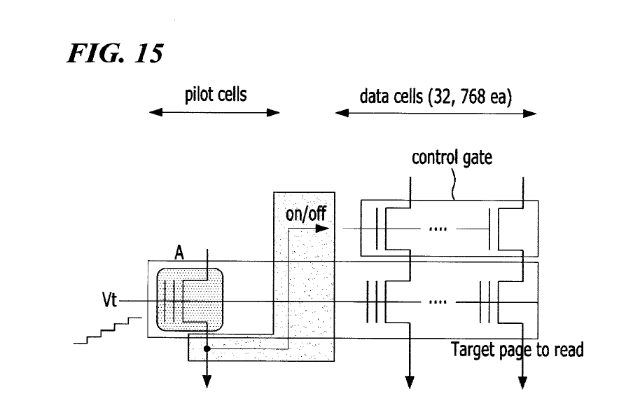

FIG. 15 exemplarily illustrates a data cell reading technique using a switch according to an aspect of the present invention.

As illustrated in FIG. 15, the step voltage may be input into the word line for the target page by the memory controller 201 or the reading module 205. When the step voltage passes through the threshold voltage Vt corresponding to pilot cell A, a switch for a control gate may be driven. As a result, current flows to the bit lines of the data cells and the data cells may be read according to an adaptive threshold voltage value determined by pilot cell A.

Pilot cells B, C, and D may also be sequentially implemented in the same scheme as pilot cell A through different threshold voltage values at different timings.

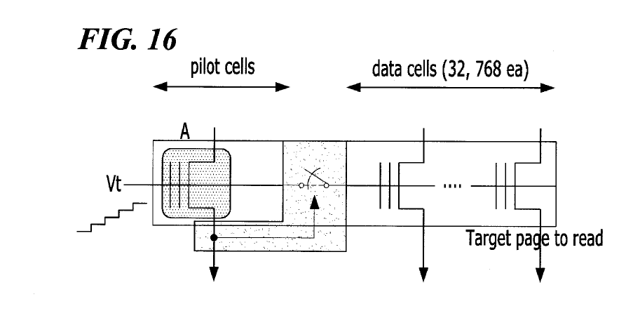

FIG. 16 exemplarily illustrates a data cell reading technique using a switch according to an aspect of the present invention.

As illustrated in FIG. 16, drain voltage of the pilot cell may be directly connected to the data cell by the switch for accessing the word line for the data cell. According to an aspect of the present invention, when the step voltage passes through the threshold voltage Vt corresponding to pilot cell A, the switch does not allow the current to flow to the control gate but allows the current to directly flow to the gates of the data cells. Therefore, the change in nominal values may also be automatically reflected on the data cell.

According to the schemes, the change in threshold voltage values may be directly reflected on the data cells through the pilot cells. The adaptive implementations do not require additional calculation to the existing mechanism.

In an additional aspect of the present invention, in reading the data for the data cell, the pilot cells are grouped to be used in order to achieve additional robustness. That is, a plurality of pilot cells may be used with respect to the respective nominal values. A group of the pilot cells may be commonly used with respect to one data block or one page.

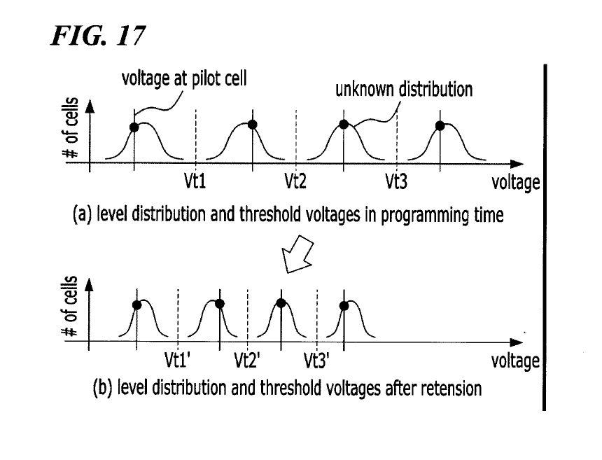

FIG. 17 exemplarily illustrates a change in threshold voltage after data programming.

When a threshold voltage level for the data cell is determined by previously referring to the pilot cells, an appropriate threshold voltage value may be found without determining the response characteristics of the respective cells even though the voltage level is changed after programming the data. As a result, when the pilot cells are used, more robust threshold voltage values may be generated without wasting the storage space.

As illustrated in FIG. 17, level distribution of the threshold voltage values at a programming time may be changed as illustrated in FIGS. 17(a) to 17(d) as the time elapses. However, the technique according to an aspect of the present invention may find the optimal threshold voltage value for the data cell through the voltage value read in the pilot cell in spite of the change in threshold voltage values. That is, according to an aspect of the present invention, a reading error probability of the data cell due to the change in threshold voltage values may be reduced.

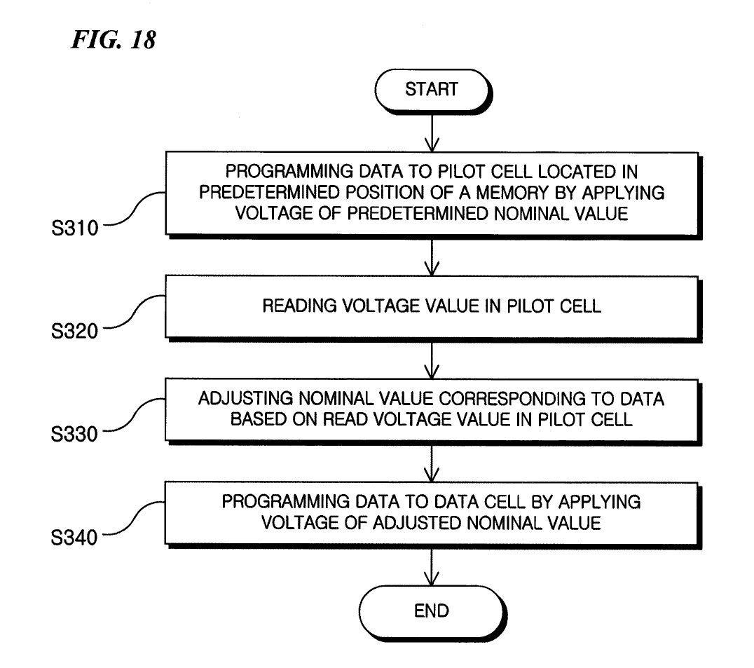

FIG. 18 is a flowchart of a data processing method of a memory according to an aspect of the present invention. It will be apparent to those skilled in the art that additional steps other than steps illustrated in FIG. 18 may be included in the method and some steps may be omitted.

As illustrated in FIG. 18, the memory controller applies voltage of a predetermined nominal value to a pilot cell at a predetermined position in the memory to program data (S310). According to an aspect of the present invention, the pilot cell is positioned within the same block or page as the data cell. Further, the pilot cell corresponds to each of one or more nominal values used for programming the memory. According to an aspect of the present invention, the pilot cell includes a plurality of cells corresponding to a plurality of nominal values used for programming the memory, respectively.

Next, the memory controller reads the written voltage value of the pilot cell (S320). In this case, the memory controller may read the voltage value of the pilot cell with higher resolution than the voltage step among the respective data for programming. For example, when the nominal value for each data for programming has a voltage step of 1 V, the memory controller may read the voltage value of the pilot cell with resolution of 0.2 V which is a higher resolution than an interval of 1 V.

Next, the memory controller adjusts the nominal value corresponding to the data of the pilot cell based on the voltage value of the read voltage of the pilot cell (S330). In this case, the memory controller calculates a difference value between the read voltage value of the pilot cell and a predetermined nominal value and adds the calculated difference value to the predetermined nominal value to obtain the adjusted nominal value. According to another aspect of the present invention, the memory controller calculates a ratio between the read voltage value of the pilot cell and the predetermined nominal value and scales the predetermined nominal value based on the calculated ratio to obtain the adjusted nominal value.

The memory controller programs the data to the data cell of the memory by using the adjusted nominal value (S340).

Meanwhile, according to an aspect of the present invention, the memory controller may obtain information on the number of erase times of a block or the number of write times of a page at which the pilot cell is positioned. The memory controller may shift the position of the pilot cell based on the information on the number of erase times or the information on the number of write times.

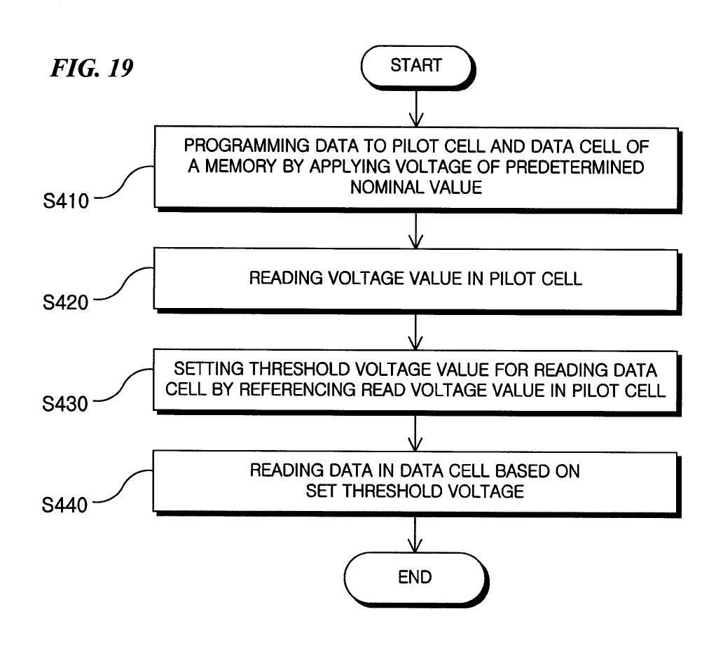

FIG. 19 is a flowchart for a data processing method of a memory according to another aspect of the present invention. It will be apparent to those skilled in the art that additional steps other than steps illustrated in FIG. 19 may be included in the method and some steps may be omitted.

As illustrated in FIG. 19, the memory controller programs data to the pilot cell and the data cell in the memory by using voltage of the predetermined nominal value (S410). As described above, the pilot cell indicates a cell at a predetermined position corresponding to each of at least one nominal value used for programming the memory. According to an aspect of the present invention, the pilot cell may include a plurality of cells corresponding to a plurality of nominal values used for programming the memory, respectively. The pilot cell may be positioned in the same block or the same page as the data cell.

Next, the memory controller reads the written voltage value of the pilot cell (S420). In this case, the memory controller may read the voltage value of the pilot cell with higher resolution than the voltage step among the respective data for programming.

Next, the memory controller sets a threshold voltage value for reading the data cell by referring to the read voltage value of the pilot cell (S430). The threshold voltage value is used as reading voltage of the data cell and according to an aspect, the threshold voltage value may be set to a value lower than the read voltage value of the pilot cell by a predetermined level. Further, according to an aspect of the present invention, the memory controller may obtain the reading voltage values of the plurality of pilot cells programmed by using the same nominal value in the memory and set the threshold voltage value based on an average of the obtained read voltage values of the plurality of pilot cells.

The memory controller reads the data of the data cell of the memory based on the set threshold voltage value (S440).

Meanwhile, according to an aspect of the present invention, the memory controller may obtain information on the number of erase times of a block or the number of write times of a page at which the pilot cell is positioned. The memory controller may shift the position of the pilot cell based on the information on the number of erase times or the information on the number of write times.

Those skilled in the art of the present invention will appreciate that various exemplary logic blocks, modules, processors, means, circuits, and algorithm steps can be implemented by electronic hardware, various types of programs or design codes (designated as “software” herein for easy description), or a combination thereof described in association with the exemplary embodiments disclosed herein. In order to clearly describe the intercompatibility of the hardware and the software, various exemplary components, blocks, modules, circuits, and steps have been generally described above in association with functions thereof. Whether the functions are implemented as the hardware or software depends on design restrictions given to a specific application and an entire system. Those skilled in the art of the present invention may implement functions described by various methods with respect to each specific application, but it should not be analyzed that the implementation determination departs from the scope of the present invention.

Various exemplary embodiments presented herein may be implemented as manufactured articles using a method, an apparatus, or a standard programming and/or engineering technique. The term “manufactured article” includes a computer program, a carrier, or a medium which is accessible by a predetermined computer-readable device. For example, a computer-readable medium includes a magnetic storage device (for example, a hard disk, a floppy disk, a magnetic strip, or the like), an optical disk (for example, a CD, a DVD, or the like), a smart card, and a flash memory device (for example, an EEPROM, a card, a stick, a key drive, or the like), but is not limited thereto. Further, various storage media presented herein include one or more devices and/or other machine-readable media for storing information. The term “machine-readable media” include a wireless channel and various other media that can store, possess and/or transfer command(s) and/or data, but are not limited thereto.

It will be appreciated that a specific order or a hierarchical structure of steps in the presented processes is one example of exemplary accesses. It will be appreciated that the specific order or the hierarchical structure of the steps in the processes within the scope of the present invention may be rearranged based on design priorities. Appended method claims provide elements of various steps in a sample order, but it does not mean that the method claims are limited to the presented specific order or hierarchical structure.

The description of the presented exemplary embodiments is provided so that those skilled in the art of the present invention use or implement the present invention. It will be apparent to those skilled in the art that various modifications of the exemplary embodiments will be apparent to those skilled in the art and general principles defined herein can be applied to other exemplary embodiments without departing from the scope of the present invention. Therefore, the present invention is not limited to the exemplary embodiments presented herein, but should be analyzed within the widest range which is consistent with the principles and new features presented herein.

### MODE FOR INVENTION

As previously described, mode for invention is fully described in best mode

### INDUSTRIAL APPLICABILITY

Present invention may be applied to various memories and memory systems which includes the memories.

1. A data processing method in a memory, comprising:
programming data by applying a voltage having a predetermined nominal value to a pilot cell at a predetermined position in the memory;
reading a written voltage value of the pilot cell;
adjusting a nominal value corresponding to the data based on the read voltage value of the pilot cell; and
programming the data to a data cell of the memory by using the adjusted nominal value.

2. The data processing method of claim 1, wherein in the reading, the voltage value of the pilot cell is read with higher resolution than a voltage step among the respective data for the programming.

3. The data processing method of claim 1, wherein the adjusting includes:
calculating a difference value between the read voltage value of the pilot cell and the predetermined nominal value; and
obtaining the adjusted nominal value by adding the calculated difference value to the predetermined nominal value.

4. The data processing method of claim 1, wherein the adjusting includes:
calculating a ratio between the read voltage value of the pilot cell and the predetermined nominal value; and
obtaining the adjusted nominal value by scaling the predetermined nominal value based on the calculated ratio.

5. The data processing method of claim 1, wherein the pilot cell is positioned in the same block or page as the data cell.

6. The data processing method of claim 5, further comprising:
obtaining information on the number of erase times of a block or information on the number of write times of a page at which the pilot cell is positioned; and
shifting the position of the pilot cell based on the information on the number of erase times or the information on the number of write times.

7. The data processing method of claim 1, wherein the pilot cell includes a plurality of cells corresponding to a plurality of nominal values used for programming the memory, respectively.

8. A memory system comprising:
a memory having a plurality of physical blocks, each of the plurality of physical blocks including a plurality of pages; and
a memory controller configured to control the memory,
wherein the memory controller includes a programming module for writing/erasing data in/from the memory, a reading module for reading the data written in the memory, and a control module controlling the programming module and the reading module,
the programming module programs data by applying a voltage having a predetermined nominal value to a pilot cell at a predetermined position in the memory,
the reading module reads a written voltage value of the pilot cell, and
the control module adjusts a nominal value corresponding to the data based on the read voltage value of the pilot cell and programs the data to a data cell of the memory by using the adjusted nominal value.

9. A data processing method in a memory, comprising:
programming data to a pilot cell and a data cell in the memory by using voltage of a predetermined nominal value, wherein the pilot cell is a cell at a predetermined position corresponding to each nominal value used for programming the memory;
reading a written voltage value of the pilot cell;
setting a threshold voltage value for reading the data cell by referring to the read voltage value of the pilot cell; and
reading the data of the data cell of the memory based on the set threshold voltage value.

10. The data processing method of claim 9, wherein in the reading, the voltage value of the pilot cell is read with higher resolution than a voltage step among the respective data for the programming.

11. The data processing method of claim 9, wherein the pilot cell is positioned in the same block or page as the data cell.

12. The data processing method of claim 11, further comprising:
obtaining information on the number of erase times of a block or information on the number of write times of a page at which the pilot cell is positioned; and
shifting the pilot cell based on information on the number of erase times or information on the number of write times.

13. The data processing method of claim 9, wherein the pilot cell includes a plurality of cells corresponding to a plurality of nominal values used for programming the memory, respectively.

14. The data processing method of claim 9, wherein the setting of the threshold voltage value includes obtaining read voltage values of a plurality of pilot cells programmed by using the same nominal value in the memory, and the threshold voltage value is set based on an average of the obtained read voltage values of the plurality of pilot cells.

15. A memory system comprising:
a memory having a plurality of physical blocks, each of the plurality of physical blocks including a plurality of pages; and
a memory controller configured to control the memory,
wherein the memory controller includes a programming module for writing/erasing data in/from the memory, a reading module for reading the data written in the memory, and a control module controlling the programming module and the reading module,
the programming module programs data to a pilot cell and a data cell in the memory by using voltage having a predetermined nominal value, wherein the pilot cell is a cell at a predetermined position corresponding to each of at least one nominal value used for programming the memory,
the reading module reads a written voltage value of the pilot cell,
the control module sets a threshold voltage value for reading the data cell by referring to the read voltage value of the pilot cell, and
the reading module reads the data of the memory cell of the memory based on the set threshold voltage value.
